(19) United States
(12) Patent Application Publication
(10) Pub. No.: US 2024/0055220 A1
(43) Pub. Date: Feb. 15, 2024

(54) Charged Particle Beam Device

(71) Applicant: Hitachi High-Tech Corporation, Minato-ku, Tokyo (JP)

(72) Inventor: Yuka II, Tokyo (JP)

(21) Appl. No.: 18/267,502

(22) PCT Filed: Dec. 23, 2020
(86) PCT No.: PCT/JP2020/048255

§ 371 Date: Jun. 15, 2023

(51) Int. Cl. H01J 37/20; H01J 37/304; H01J 37/28; H01J 37/305

(52) U.S. Cl. CPC H01J 37/20; H01J 37/3045; H01J 37/28; H01J 37/3056; H01J 2237/208; H01J 2237/31749

(57) ABSTRACT

A charged particle beam device includes a sample stage on which a sample is mounted and moved, a charged particle beam irradiation optical system irradiating with a charged particle beam, a sample piece movement unit holding and conveying a sample piece extracted from the sample, a holder fixing table holding a sample piece holder to which the sample piece is transferred, and a computer. When allowing the sample piece movement unit to approach the sample piece, the computer selects a matching region for performing image matching between a reference image obtained in advance by irradiating the sample with the charged particle beam and a comparison image obtained by irradiating the sample, which is an extraction target for the sample piece, with the charged particle beam.

### TECHNICAL FIELD

The present invention relates to a charged particle beam device having a sample extraction function.

### BACKGROUND ART

A focused ion beam (FIB) method, which is one of machining methods using a charged particle beam device, is a fine machining method using a sputtering phenomenon of target constituent atoms by irradiating a sample with a focused ion beam. In recent years, an FIB-SEM composite apparatus, which combines an FIB device and a scanning electron microscope (SEM), has been commercialized. The FIB-SEM composite apparatus is designed so that an irradiation axis of the ion beam and an irradiation axis of the electron beam intersect at the same point, and thus, a FIB machining cross section can be observed by SEM without moving the sample.

Purposes of the FIB-SEM composite apparatus in the semiconductor field include, for example, structural observation, dimension measurement, investigation/confirmation of product reproducibility and reliability, and the like in device development and defect analysis. Here, since machining and observation at a plurality of locations in a semiconductor wafer or a semiconductor device are essential, shortening of an operating time, saving of labors of an operator, and elimination of a need for skill are required for the apparatus.

For example, PTL 1 discloses a technique of extracting a target location in a sample completely automatically or with performance similar thereto and fixing the target location to the sample piece holder for machining. In the automatic extraction of the sample, processes of accurately recognizing the target location, machining and extracting the sample to an appropriate size, and then fixing the sample at a desired position are performed.

PTL 2 discloses a technique of performing an extraction operation of a sample piece by performing detection of contact/separation among the sample piece, a needle extracting the sample piece, and a sample piece holder to which the sample piece is attached by measuring electrical conduction and managing processes for a machining time when the conduction cannot be obtained.

### CITATION LIST

### Patent Literature

PTL 1: JP2016-050854A

PTL 2: JP2018-116865A

### SUMMARY OF INVENTION

### Technical Problem

A series of operations related to automatic extraction of a sample piece are required to be performed stably and accurately without damaging both a sample and a device. Until now, the automatic extraction of the sample piece has been performed by using scanning ion microscope (SIM) images, SEM images, absorption current images, and various image processing techniques. However, when a target sample is a semiconductor wafer or a semiconductor device, there is an increase of number of cases where the accuracy and stability of the automatic extraction of the sample piece depend on a structure of the sample due to miniaturization and diversification of a device structure.

The present invention is to provide a charged particle beam device capable of performing automatic extraction of a sample piece accurately and stably.

### Solution to Problem

Among the inventions disclosed in the present application, a representative outline (outline=brief description) is as follows.

A charged particle beam device according to a representative embodiment of the present disclosure automatically extracts a sample piece from a sample. The charged particle beam device includes a sample stage on which a sample is mounted and moved, a charged particle beam irradiation optical system irradiating with a charged particle beam, a sample piece movement unit holding and conveying the sample piece extracted from the sample, a holder fixing table holding the sample piece holder to which the sample piece is transferred, and a computer. When the sample piece movement unit approaches the sample piece, the computer selects a matching region for performing image matching between a reference image obtained in advance by irradiating the sample with the charged particle beam and a comparison image obtained by irradiating the sample, which is an extraction target for the sample piece, with the charged particle beam.

### Advantageous Effects of Invention

Among the inventions disclosed in the present application, the effects obtained by representative ones are briefly described below.

That is, according to representative embodiments of the present disclosure, the automatic extraction of the sample piece can be executed accurately and stably.

### BRIEF DESCRIPTION OF DRAWINGS

FIG. 1 is a configuration diagram illustrating an example of an automatic sample piece producing apparatus provided with a charged particle beam device according to a first embodiment of the present invention.

FIG. 2 is a flowchart mainly illustrating an example of an initial setting process in the flowchart illustrating operations of the charged particle beam device according to the first embodiment of the present invention.

FIG. 3 is a plan view of a sample piece holder.

FIG. 4 is a side view of the sample piece holder.

FIG. 5 is a flowchart illustrating an example of a method of registering a reference image and setting an image matching region.

FIG. 6 is a plan view illustrating a sample piece formed on a sample of the automatic sample piece producing apparatus according to the first embodiment of the present invention.

FIG. 7 is a diagram illustrating an example of a machining mark shape and a sample piece shape on a sample recognized from the reference image in the charged particle beam device according to the first embodiment of the present invention.

FIG. 8 is a diagram illustrating an example of an image in which a region outside a frame line of the machining mark shape is masked in the charged particle beam device according to the first embodiment of the present invention.

FIG. 9 is a conceptual diagram of the image matching when storing the region outside the frame line of the machining mark shape is selected.

FIGS. 10A and 10B are conceptual diagrams illustrating the image matching when storing a designated region.

FIG. 11 is a diagram illustrating a template for a tip of a needle obtained by a focused ion beam.

FIG. 12 is a diagram illustrating a template for a tip of a needle obtained by an electron beam.

FIGS. 13A and 13B are diagrams illustrating another example of an image matching method.

FIG. 14 is a flowchart illustrating an example of a sample piece pickup process according to the first embodiment of the present invention.

FIG. 15 is a diagram illustrating a vicinity of a tip of a needle in an image obtained by the focused ion beam of the charged particle beam device according to the first embodiment of the present invention.

FIG. 16 is a diagram illustrating a vicinity of a tip of a needle in an image obtained by the electron beam of the charged particle beam device according to the first embodiment of the present invention.

FIG. 17 is a diagram illustrating a tip of a needle and a sample piece in image data obtained by the focused ion beam of the charged particle beam device according to the first embodiment of the present invention.

FIG. 18 is a diagram illustrating a tip of a needle and a sample piece in image data obtained by the electron beam of the charged particle beam device according to the first embodiment of the present invention.

FIG. 19 is a diagram illustrating a machining range including connection machining positions of a needle and a sample piece in the image data obtained by the focused ion beam of the charged particle beam device according to the first embodiment of the present invention.

FIG. 20 is a diagram illustrating cut machining positions of a sample and a support portion of a sample piece in the image data obtained by the focused ion beam of the charged particle beam device according to the first embodiment of the present invention.

FIG. 21 is a diagram illustrating a state in which a sample piece is extracted in the image data obtained by the electron beam of the charged particle beam device according to the first embodiment of the present invention.

FIG. 22 is a diagram illustrating a state in which a needle to which a sample piece is connected is retracted in the image data obtained by the electron beam of the charged particle beam device according to the first embodiment of the present invention.

FIG. 23 is a diagram illustrating a state of a vicinity of a tip of a needle when the needle is not rotated.

FIG. 24 is a diagram illustrating a state of a vicinity of a tip of a needle when the needle is not rotated.

FIG. 25 is a diagram illustrating a state of a vicinity of a tip of a needle when the needle is rotated.

FIG. 26 is a diagram illustrating a state of a vicinity of a tip of a needle when the needle is rotated.

FIG. 27 is a diagram illustrating a state of a vicinity of a tip of a needle when the needle is rotated.

FIG. 28 is a diagram illustrating a state of a vicinity of a tip of a needle when the needle is rotated.

FIG. 29 is a diagram illustrating a reference image according to the second embodiment of the present invention.

FIG. 30 is a conceptual diagram illustrating an example of image matching by using the training-completed model.

FIGS. 31A to 31C are diagrams illustrating another example of image matching by using the training-completed model.

FIG. 32 is a conceptual diagram illustrating another example of image matching by using the training-completed model.

FIGS. 33A and 33B are diagrams illustrating a specific example of FIG. 32.

### DESCRIPTION OF EMBODIMENTS

[Supplement to Problem or the Like]

In an existing automatic extraction of a sample, as a first step for extracting a sample piece, a needle approaches the sample piece by performing the following processing.

An absorption current image obtained by irradiating the needle with a charged particle beam before performing the automatic extraction of the sample, each reference image produced in advance from a secondary electron image obtained by irradiating the sample piece with the charged particle beam, an absorption current image obtained by irradiating the needle with the charged particle beam while executing the automatic sample piece extraction sequence, and a comparison image produced from the secondary electron image obtained by irradiating the sample piece with the charged particle beam are acquired.

Next, positional coordinates of a tip of the needle and positional coordinates of locations to which the tip of the needle is to be approached in the sample piece to be extracted are determined by image recognition, and the tip of the needle approaches the determined positional coordinates. Here, contrast value, brightness value, scan speed, image size, or the like can be set in advance from the reference image of the sample piece to be acquired.

However, since a function of masking a portion of the image is not provided, image matching is performed by using an entire region of the acquired reference image and comparison image to determine a needle approaching position. Therefore, it has been clarified that, when the sample piece is extracted from the sample having a fine and periodic complicated pattern such as a distal-end device, a probability of matching recognition failure increases. When a recognition failure such as “recognition is not possible” in the image matching occurs, the automatic sample piece extraction sequence is ended and the next sequence is started, so that a success rate of the entire automatic sample extraction process decreases.

When a recognition failure such as “a position that is not a needle approaching position is recognized as a needle approaching position” occurs, the sample or the sample piece (there is a risk of contact with not only the sample piece but also the sample) is in contact with the needle, and a risk of damage or deformation of the sample, the sample piece, or the needle increases. Damage and deformation of samples or sample pieces are a big problem when handling valuable samples. When the needle is damaged or deformed, the needle needs to be replaced. In either case, not only performance is significantly degraded, but also the automatic extraction of the sample piece that is an original purpose cannot be achieved.

Therefore, in the following embodiments, by masking a location having a repetitive structure or the like unique to the sample, an accuracy of a position-alignment of the needle in the automatic sample piece extraction sequence is improved. In the following embodiments, artificial intelligence (AI) is used to detect a training-completed repetitive pattern region in the image, and masking is performed on the detected repetitive pattern region, so that the automatic sample piece extraction sequence can be executed accurately and stably.

In the following description, the embodiments of the present disclosure will be described with reference to the drawings. Each embodiment described below is an example for realizing the present disclosure, and does not limit the technical scope of the present disclosure. Note that, in the embodiments, members having the same functions are denoted by the same reference numerals, and redundant description thereof will be omitted unless particularly necessary.

### First Embodiment

<Configuration of Charged Particle Beam System>

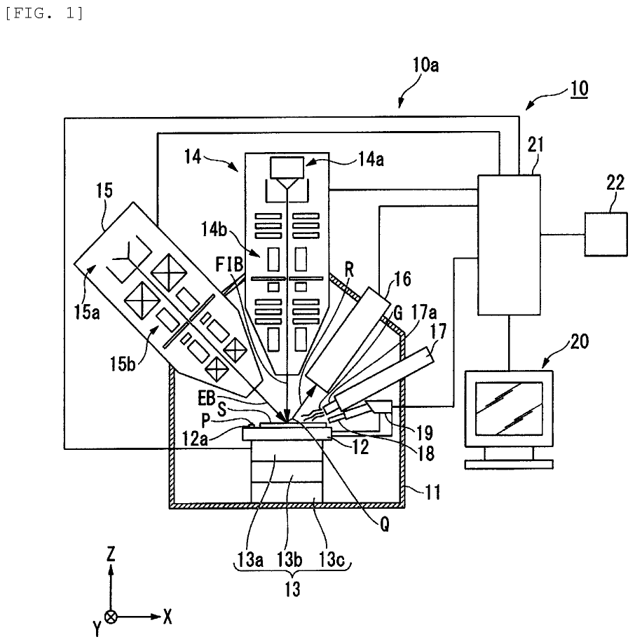

FIG. 1 is a configuration diagram illustrating an example of an automatic sample piece producing apparatus provided with a charged particle beam device according to the first embodiment of the present invention. As illustrated in FIG. 1, the automatic sample piece producing apparatus 10 includes a charged particle beam device 10a and the like.

The charged particle beam device 10a includes a sample chamber 11 of which an interior can be maintained in a vacuum state, a stage 12 capable of fixing a sample S and a sample piece holder P inside the sample chamber 11, a stage driving mechanism 13 driving the stage 12, and the like.

The charged particle beam device 10a includes a focused ion beam irradiation optical system 14 irradiating an irradiation target within a predetermined irradiation region (scanning range) inside the sample chamber 11 with a FIB. The charged particle beam device 10a includes an electron beam irradiation optical system 15 irradiating the irradiation target within a predetermined irradiation region inside the sample chamber 11 with an electron beam (EB). The charged particle beam device 10a includes a detector 16 detecting secondary charged particles (secondary electrons, secondary ions) R generated from the irradiation target by irradiation with the focused ion beam or the electron beam.

The charged particle beam device 10a includes a gas supply unit 17 supplying gas G to a surface of the irradiation target. The gas supply unit 17 is specifically configured with a nozzle 17a having an outer diameter about 200 μm and the like. The charged particle beam device 10a includes a needle 18 picking up (extracting) a minute sample piece Q from the sample S fixed to the stage 12, holding the picked-up sample piece Q and transferring sample piece Q to the sample piece holder P, and a needle driving mechanism 19 conveying the sample piece Q by driving the needle driving mechanism 19. Hereinafter, the needle 18 and the needle driving mechanism 19 may be collectively referred to as a sample piece transfer unit. The charged particle beam device 10a includes a display device 20 displaying image data based on the secondary charged particles R detected by the detector 16, a computer 21, and an input device 22.

Note that each of irradiation targets of the focused ion beam irradiation optical system 14 and the electron beam irradiation optical system 15 includes the sample S, the sample piece Q, the needle 18 or the sample piece holder P existing within the irradiation region, and the like, which are fixed to the stage 12.

The charged particle beam device 10a irradiates the surface of the irradiation target with the focused ion beam while scanning, so that imaging an irradiated portion, various machining (for example, excavation, trim machining, and the like) by sputtering, forming a deposition film, and the like can be performed. The charged particle beam device 10a can perform machining of forming the sample piece Q (for example, a thin piece sample, a needle-shaped sample, or the like) for transmission observation by a transmission electron microscope or an analysis sample piece for using the electron beam from the sample S. The charged particle beam device 10a can perform machining of converting the sample piece Q transferred to the sample piece holder P into a thin film having a desired thickness (for example, 5 to 100 nm) suitable for the transmission observation with the transmission electron microscope. The charged particle beam device 10a can observe a surface of the irradiation target by irradiating the surface of the irradiation target such as the sample piece Q and the needle 18 with the focused ion beam or the electron beam while scanning.

The sample chamber 11 is configured to be capable of being evacuated to a desired vacuum state by an exhaust device (not illustrated) and to be capable of maintaining the desired vacuum state. The stage 12 holds the sample S. The stage 12 includes a holder fixing table 12a holding the sample piece holder P. The holder fixing table 12a may be configured to be capable of mounting the plurality of sample piece holders P thereon.

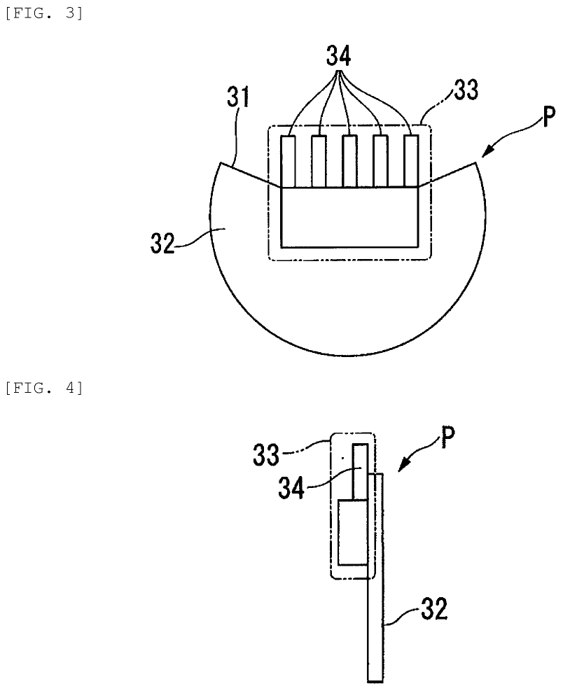

FIG. 3 is a plan view of the sample piece holder. FIG. 4 is a side view of the sample piece holder. The sample piece holder P includes a substantially semicircular plate-shaped base portion 32 including a notch portion 31, and a sample table 33 fixed to the notch portion 31. The base portion 32 is made of, for example, metal and is formed with a circular plate shape having a diameter of 3 mm and a thickness of 50 μm. The sample table 33 is formed from, for example, a silicon wafer by the semiconductor producing process and is adhered to the notch portion 31 with a conductive adhesive. The sample table 33 has a comb-like shape and has a plurality of (for example, 5, 10, 15, 20, or the like) columnar portions (hereinafter also referred to as pillars) 34 to which the sample piece Q is transferred, the columnar portions 34 protruding while separately arranged.

By varying a width of each columnar portion 34, associating the extraction location of the sample piece Q on the sample S, the sample piece Q transferred to each columnar portion 34, and the image of the columnar portion 34 with each other, and storing the extraction location in the computer 21 in association with the corresponding sample piece holder P, even when the plurality of sample pieces Q are produced from one sample S, each sample piece Q can be recognized without error, and the subsequent analysis such as the transmission electron microscope can also be performed without error in the association between the sample piece Q and the extraction location on the sample S. Each columnar portion 34 is formed to include a tip portion having a thickness of, for example, 10 μm or less, 5 μm or less, or the like and holds the sample piece Q mounted on the tip portion.

Note that the shape of the base portion 32 is not limited to the circular plate-like shape having a diameter of 3 mm and a thickness of 50 μm as described above, but, for example, the base portion 32 may have a square plate-like shape having a length of 5 mm, a height of 2 mm, and a thickness of 50 μm. That is, the shape of the base portion 32 may be a shape capable of mounting the sample pieces on the stage 12 to be introduced into the subsequent transmission electron microscope and a shape where the sample piece Q mounted on the sample table 33 is all positioned within a movable range of the stage 12.

The stage driving mechanism 13 is accommodated inside the sample chamber 11 in a state of being connected to the stage 12 and displaces the stage 12 along a predetermined axis according to a control signal output from the computer 21. The stage driving mechanism 13 includes a moving mechanism 13a moving the stage 12 in parallel along at least an X-axis and a Y-axis that are parallel to the horizontal plane and perpendicular to each other and a vertical Z-axis that is perpendicular to the X-axis and the Y-axis. The stage driving mechanism 13 also includes a tilting mechanism 13b tilting the stage 12 around the X-axis or the Y-axis and a rotating mechanism 13c rotating the stage 12 around the Z-axis.

In the focused ion beam irradiation optical system 14, a beam emission unit (not illustrated) inside the sample chamber 11 is fixed in the sample chamber 11 while facing the stage 12 at a position vertically above the stage 12 in the irradiation region and directing an optical axis vertically. Accordingly, the focused ion beam irradiation optical system 14 can irradiate the irradiation target such as the sample S, the sample piece Q, and the needle 18 existing within the irradiation region, which are fixed to the stage 12, with the focused ion beam directing vertically downward from the above.

The focused ion beam irradiation optical system 14 includes an ion source 14a generating ions and an ion optical system 14b focusing and deflecting the ions extracted from the ion source 14a. The ion source 14a and the ion optical system 14b are controlled according to control signals output from the computer 21, and the irradiation position, irradiation conditions, and the like of the focused ion beam are controlled by the computer 21. The ion source 14a is, for example, a liquid metal ion source using liquid gallium or the like, a plasma ion source, a gas field ionization ion source, or the like. The ion optical system 14b includes, for example, a first electrostatic lens such as a condenser lens, an electrostatic deflector, a second electrostatic lens such as an objective lens, and the like.

In the electron beam irradiation optical system 15, the beam emission unit (not illustrated) inside the sample chamber 11 faces the stage 12 in the tilt direction tilted at a predetermined angle (for example, 60°) with respect to the vertical direction of the stage 12 in the irradiation region and is fixed in the sample chamber 11 with the optical axis parallel to the tilt direction. Accordingly, the irradiation target such as the sample S, the sample piece Q, and the needle 18 existing within the irradiation region, which are fixed to the stage 12, can be irradiated with the electron beam directing downward from the above in the tilt direction.

The electron beam irradiation optical system 15 includes an electron source 15a generating electrons and an electron optical system 15b focusing and deflecting the electrons emitted from the electron source 15a. The electron source 15a and the electron optical system 15b are controlled according to control signals output from the computer 21, and the computer 21 controls the irradiation position and irradiation conditions of the electron beam. The electron optical system 15b includes, for example, an electromagnetic lens, a deflector, and the like.

Note that the positions of the electron beam irradiation optical system 15 and the focused ion beam irradiation optical system 14 may be replaced, and the electron beam irradiation optical system 15 was tilted in the vertical direction, and the focused ion beam irradiation optical system 14 may be arranged in a tilt direction tilted by a predetermined angle with respect to the vertical direction. The electron beam irradiation optical system 15 and the focused ion beam irradiation optical system 14 may not be both arranged in the vertical direction.

When the irradiation target such as the sample S and the needle 18 is irradiated with the focused ion beam or the electron beam, the detector 16 detects the intensity (that is, the amount of secondary charged particles) of the secondary charged particles (secondary electrons and secondary ions) R emitted from the irradiation target and outputs information on the detected amount of secondary charged particles R. The detector 16 is arranged at the position where the amount of the secondary charged particles R can be detected inside the sample chamber 11 and, for example, at the position obliquely above the irradiation target such as the sample S in the irradiation region to be fixed to the sample chamber 11.

The gas supply unit 17 is fixed to the sample chamber 11. The gas supply unit 17 includes a gas injection unit (also referred to as a nozzle) inside the sample chamber 11 and is arranged facing the stage 12. The gas supply unit 17 supplies an etching gas for selectively promoting the etching of the sample S by the focused ion beam according to a material of the sample S and a deposition gas or the like for forming a deposition film by deposits of metal or an insulator on the surface of the sample S to the sample S.

For example, etching is selectively promoted by supplying the etching gas such as xenon fluoride for a silicon (Si)-based sample S and water vapor (H₂O) for an organic-based sample S to the sample S together with irradiation with the focused ion beam. For example, by supplying the deposition gas containing platinum, carbon, tungsten, or the like to the sample S together with irradiating with the focused ion beam, solid components decomposed from the deposition gas can be deposited on the surface of the sample S. As specific examples of the deposition gas, carbon-containing gas such as phenanthrene and naphthalene, platinum-containing gas such as trimethyl-ethylcyclopentadienyl-platinum, tungsten-containing gas such as tungsten hexacarbonyl, and the like are exemplified. Note that, according to the type of supplied gas, etching and deposition can also be performed by irradiating electron beams.

The needle driving mechanism 19 is accommodated inside the sample chamber 11 with the needle 18 connected thereto and drives the needle 18 according to the control signal output from the computer 21. The needle driving mechanism 19 is provided integrally with the stage 12, and the stage 12 is integrally moved when, for example, the stage 12 is rotated around the tilt axis (that is, the X-axis or the Y-axis) by the tilting mechanism 13b.

The needle driving mechanism 19 includes a moving mechanism (not illustrated) moving the needle 18 in parallel along each axis of the three-dimensional coordinate axes and a rotating mechanism (not illustrated) rotating the needle 18 around the central axis of the needle 18. Note that the three-dimensional coordinate axes are independent from those of a perpendicular three-axis coordinate system of the sample stage and, when the surface of the stage 12 is in a tilt state and a rotation state in the perpendicular three-axis coordinate system with two-dimensional coordinate axes parallel to the surface of the stage 12, the coordinate system tilts and rotates.

The computer 21 is arranged outside the sample chamber 11 and is connected to the display device 20 and the input device 22 such as a mouse and a keyboard outputting signals according to the input operation of the operator. The computer 21 comprehensively controls the operation of the charged particle beam system 10a based on signals output from the input device 22 or signals generated by preset automatic operation control process.

The computer 21 converts the detected amount of the secondary charged particles R detected by the detector 16 while scanning the irradiation position of the charged particle beam into a luminance signal associated with the irradiation position and generates the image data indicating the shape of the irradiation target by the two-dimensional positional distribution of the detected amount of the secondary charged particles R. In an absorption current image mode, the computer 21 detects an absorption current flowing through the needle 18 while scanning the irradiation position of the charged particle beam and, thus, generates absorption current image data indicating the shape of the needle 18 from the two-dimensional positional distribution (absorption current image) of the absorption current.

The computer 21 allows the display device 20 to display the screen for performing the operations such as enlarging, reducing, moving, and rotating each image data together with the generated image data. The computer 21 allows the display device 20 to display the screen for performing various settings such as mode selection and machining settings in automatic sequence control.

Next, the automatic sample piece extraction sequence executed by the computer 21 will be described. The automatic sample piece extraction sequence is an operation of automatically moving the sample piece Q formed by machining of the sample S with the charged particle beam (focused ion beam) to the sample piece holder P. The automatic sample piece extraction sequence includes an initial setting process, a sample piece pickup process, a sample piece mounting process, and a needle trimming process. Note that, in the present embodiment, the initial setting process and the sample piece pickup process will be mainly described.

<Initial Setting Process>

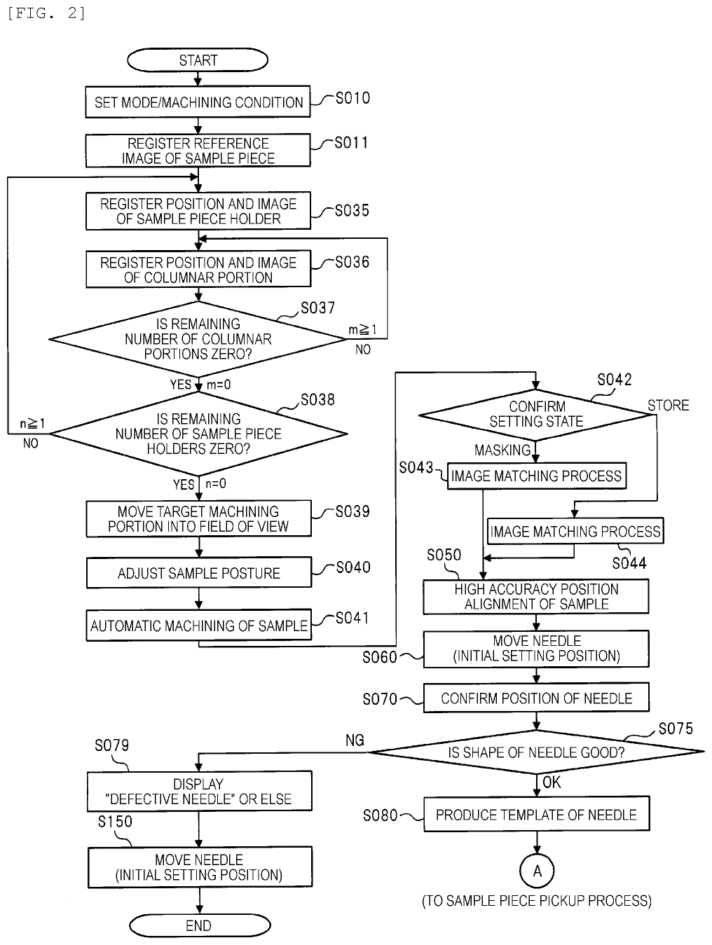

FIG. 2 is a flowchart mainly illustrating an example of the initial setting process in a flowchart illustrating operations of the charged particle beam system according to the first embodiment of the present invention. As illustrated in FIG. 2, the initial setting process includes steps S010 to S150.

First, at the start of the automatic sample piece extraction sequence, the computer 21 performs mode selection whether to use the posture control mode described later, setting of observation conditions for template matching and machining conditions (machining position, size, number, or the like) according to the input of the operator (step S010).

<<Registration of Sample-Piece Reference Image and Setting of Image Matching Region>>

Next, the computer 21 registers a sample-piece reference image and sets an image matching region. Herein, mainly a setting method in step S011 will be described in detail. FIG. 5 is a flowchart illustrating an example of a method of registering the sample-piece reference image and setting the image matching region (S011a to S011f).

First, to set the matching region of the reference image, the charged particle beam device 10a performs machining of the sample S (step S011a).

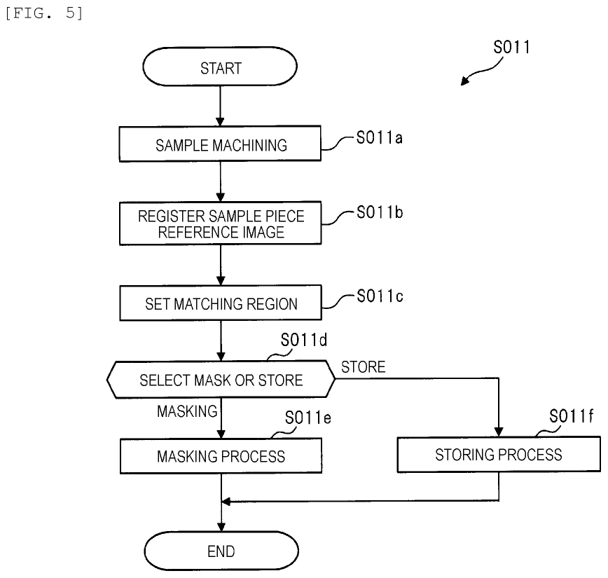

FIG. 6 is a plan view illustrating the sample piece Q formed on the sample S of the automatic sample piece producing apparatus according to the first embodiment of the present invention. A reference mark F in FIG. 6 denotes the machining range of the focused ion beam, that is, the scanning range of the focused ion beam. In FIG. 6, the inner side (white portion) of the scanning range F is a machining region H excavated by sputter machining by focused ion beam irradiation. On the other hand, in FIG. 6, a shaded portion is a region that is not sputter-machined by the focused ion beam irradiation, that is, a region that is not excavated.

A reference mark Ref in FIG. 6 denotes a reference mark (reference point) basically indicating the position where the sample piece Q is formed. The reference mark Ref has, for example, a shape in which a minute hole having a diameter of 1 μm is formed by the focused ion beam on the deposition film (for example, a square with a side of 10 μm) described later. The reference mark Ref can be recognized with good contrast by the focused ion beam or the electron beam image. For example, the deposition film is used to recognize the rough position of the sample piece Q, and a minute hole is used to perform accurate position-alignment.

The reference mark Ref is not limited to the above shape. It is also possible to use, as the reference mark Ref, the machining mark that the operator has machined into an arbitrary shape on the surface of the sample or a singular point originally possessed by the sample or the sample piece holder.

In the sample S, the sample piece Q is sputter-machined so that the peripheral portions on the side and bottom sides are scraped away while leaving a supporting portion Qa connected to the sample S, and is cantilevered on the sample S by the supporting portion Qa (FIG. 6). The longitudinal dimension of the sample piece Q is, for example, about 10 μm, 15 μm, and 20 μm, and the width (thickness) of the sample piece Q is, for example, about 500 nm, 1 μm, 2 μm, and 3 μm. Thus, the sample piece Q is a minute sample piece.

In step S011b, registration of the sample-piece reference image is performed. The computer 21 uses the charged particle beam device 10a to capture the image of the sample S, which has been machined (hereinafter also referred to as peripheral machining) as illustrated in FIG. 6 from an arbitrary direction and registers the image as a sample-piece reference image.

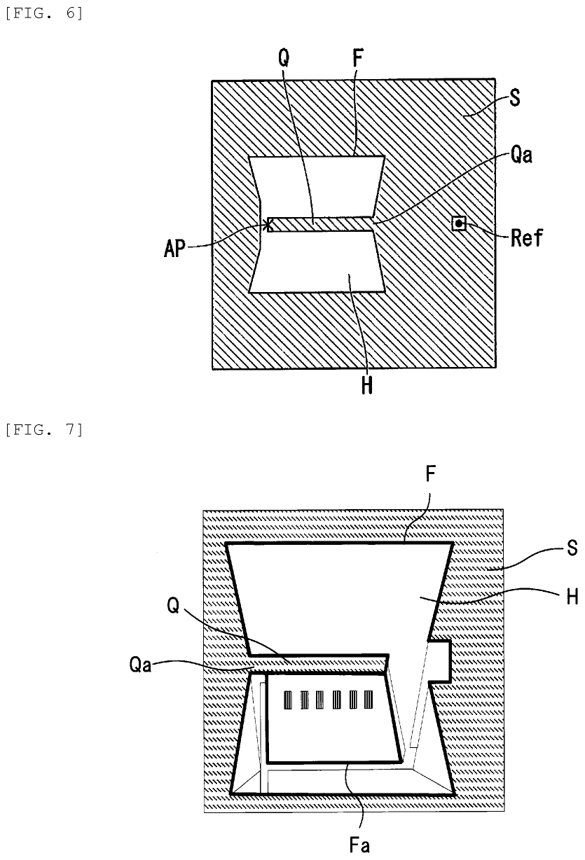

Next, the computer 21 sets a matching region (step S011c). FIG. 7 is a diagram illustrating an example of the machining mark shape and the sample piece shape on the sample recognized from the reference image in the charged particle beam device according to the first embodiment of the present invention.

The computer 21 recognizes the machining mark shape F of the peripheral machining performed in advance in the periphery of the sample piece Q and the sample piece shape Fa automatically or based on information input from the input device 22. Then, the computer 21 sets the region where the machining mark shape F and the sample piece shape Fa are recognized as the matching region (FIG. 7). Alternatively, the computer 21 may set the matching region based on arbitrary information of position, size, and number input from the input device 22. Note that, when the matching region based on arbitrary information of position, size, and number is not designated, the computer 21 may set the entire region of the reference image as the matching region.

When the computer 21 recognizes the machining mark shape F of the peripheral machining performed in advance in the periphery of the sample piece Q, the computer 21 selects whether to perform a masking process of masking the image of the region outside the frame line of the machining mark shape F illustrated in FIG. 7 or to perform a storing process of storing the region outside the frame line of the machining mark shape F (step S011d). The computer 21 stores and sets the selected processing. Note that the processing selected and set herein may be temporarily stored in an internal memory inside the computer 21 or may be stored, for example, in an external storage device outside the computer 21.

When the masking process is selected in step S011d, the masking process is performed on the reference image (step S011e). FIG. 8 is a diagram illustrating an example of the image in which the region outside the frame line of the machining mark shape is masked in the charged particle beam device according to the first embodiment of the present invention. When the masking process is selected, the computer 21 performs masking the region of the reference image outside the machining mark shape F, for example, as illustrated in FIG. 8.

On the other hand, when the storing process is selected in step S011d, the computer 21 executes the process of storing the region outside the frame line of the machining mark shape F (step S011f).

Now, the description returns to FIG. 2. When completing the registration of the sample piece reference image and the setting of the image matching region (step S011), the computer 21 produces a template for the columnar portion 34 (steps S035 to S038). In production of a template for the columnar portion 34, the computer 21 first performs a position registration process for the sample piece holder P that is installed on the holder fixing table 12a of the stage 12 by the operator (step S035). The computer 21 produces the template for the columnar portion 34 at the beginning of the sampling process. In step S035, the computer 21 produces the template for each columnar portion 34.

The computer 21 performs acquisition of the stage coordinates of each columnar portion 34, performs the template production, and stores as set of the acquisition of the stage coordinates and the template in association with each other. The computer 21 uses the acquired stage coordinates and the template for the columnar portion 34 when determining the shape of the columnar portion 34 in the template matching (superposition of the template and the image) described later.

The computer 21 stores, for example, the image itself, edge information extracted from the image, or the like in advance, as the template for the columnar portion 34 used for the template matching. In the later process, the computer 21 performs the template matching after the movement of the stage 12 and determines the shape of the columnar portion 34 based on a score of the template matching, so that the correct position of the columnar portion 34 can be recognized. Note that it is desirable that, since the accurate template matching can be performed, the same observation conditions of contrast and magnification as those for the template production are used as the observation conditions for the template matching.

The computer 21 can confirm in advance that the sample table 33 having an appropriate shape actually exists by performing the position registration process of the sample piece holder P prior to the movement of the sample piece Q described later.

In the position registration process, first, as a coarse adjustment operation, the computer 21 moves the stage 12 by the stage driving mechanism 13 and aligns position of the irradiation region with the position where the sample table 33 is attached in the sample piece holder P. Next, as a fine adjustment operation, the computer 21 produces in advance the template from a design shape (CAD information) of the sample table 33 and extracts the positions of the plurality of columnar portions 34 constituting the sample stage 33 by using the template from each image data generated by irradiation with the charged particle beam (focused ion beam and electron beam). Then, the computer 21 registers (stores) the extracted positional coordinates and image of each columnar portion 34 as an installation position of the sample piece Q (step S036). Here, the image of each columnar portion 34 is compared with a design drawing of the columnar portion, a CAD drawing, or an image of a standard product of the columnar portion 34 prepared in advance, or the like, the presence of deformation, chipping, missing, or the like of each columnar portion 34 is confirmed, and when the columnar portion 34 is defective, the fact that the columnar portion 34 is defective is stored together with the coordinate position and image of the columnar portion.

Next, it is determined whether there is any columnar portion 34 to be registered in the sample piece holder P during the current execution of the registration process (step S037). When the determination result is “NO”, that is, when the remaining number m of columnar portions 34 to be registered is 1 or more, the process returns to step S036 described above, and step S036 and S037 are repeated until the remaining number m of columnar portions 34 disappears. On the other hand, when the determination result is “YES”, that is, when the remaining number m of columnar portions 34 to be registered is zero, the process proceeds to step S038.

When the plurality of sample piece holders P are installed on the holder fixing table 12a, the computer 21 records the positional coordinate of each sample piece holder P and the image data of the corresponding sample piece holder P together with a code number for each sample piece holder P. The computer 21 stores (registers) the code number and the image data corresponding to the positional coordinates of the columnar portions 34 of the respective sample piece holders P. The computer 21 may sequentially perform the position registration process of the number of sample pieces Q for which automatic sample sampling is to be performed.

Then, the computer 21 determines whether there is any sample piece holder P to be registered (step S038). When the determination result is “NO”, that is, when the remaining number n of the sample piece holders P to be registered is 1 or more, the process returns to step S035 described above, and the steps S035 to S038 are repeated until the remaining number n of the sample piece holders P disappears. On the other hand, when the determination result is “YES”, that is, when the remaining number n of the sample piece holders P to be registered is zero, the process proceeds to step S039.

Accordingly, when several tens of sample pieces Q are automatically produced from one sample S, since the positions of the plurality of sample piece holders P are registered on the holder fixing table 12a, and the positions of the respective columnar portions 34 are image-registered, the specific sample piece holder P to which several tens of samples Q are to be attached and the specific columnar portion 34 can be immediately called within the field of view of the charged particle beam.

Note that, in the position registration process (steps S035 and S036), when the sample piece holder P itself or the columnar portion 34 is deformed or damaged and, thus, the sample piece Q is not in a state of being attached, “unusable” (notation indicating that the sample piece Q is not attached) or the like together with the positional coordinates, image data, and the code number is registered in association with each other. Accordingly, when transferring the sample piece Q described later, the “unusable” sample piece holder P or the “unusable” columnar portion 34 is skipped, the computer 21 can move the next normal sample piece holder P or the next normal columnar portion 34 into the observation field of view.

Next, the computer 21 recognizes the reference mark Ref formed in advance on the sample S by using the image data of the charged particle beam. The computer 21 recognizes the position of the sample piece Q from an existing relative positional relationship between the reference mark Ref and the sample piece Q by using the recognized reference mark Ref and moves the stage so that the position of the sample piece Q is within the observation field of view (step S039).

Next, the computer 21 drives the stage 12 by the stage driving mechanism 13 and rotates the stage 12 about the Z-axis by the angle corresponding to the posture control mode so that the posture of the sample piece Q becomes a predetermined posture (for example, a posture suitable for extraction by the needle 18) (step S040).

Next, the computer 21 starts automatic machining of the sample. The computer 21 controls each component of the charged particle beam device 10a to perform machining of the sample S to produce the sample piece, for example, illustrated in FIG. 6. Then, the computer 21 acquires the image of the sample S from which the sample piece Q is produced, for example, under the same conditions as the reference image illustrated in FIG. 7 as a comparison image (step S041).

Next, the computer 21 recognizes the reference mark Ref by using the image data of the charged particle beam and performs various image matching using an existing relative positional relationship between the reference mark Ref and the sample piece Q, the reference image, and the comparison image (steps S043 and S044 to be described later).

Before steps S043 and S044, in step S042, confirmation of setting information of processing to be selected is performed when the machining mark shape F of the peripheral machining performed in advance in the periphery of the sample piece Q is recognized. The setting information is set in step S011d described above. The computer 21 reads the setting information related to the processing selected when the machining mark shape F of the peripheral machining performed in advance in the periphery of the sample piece Q is recognized, for example, from the internal memory or the external storage device and performs confirmation of the setting information.

When the setting information prescribes that the masking process is to be performed when the machining mark shape F of the peripheral machining performed in advance in the periphery of the sample piece Q is recognized, the process of step S043 is executed.

In step S043, the masking process is first performed on the same region as the reference image for the comparison image acquired in step S041. Then, the computer 21 performs the image matching on the regions for the reference image and the comparison image, where the masking is not performed. When FIG. 8 is used as an example, the image matching is performed on a region not blackened inside the machining mark shape F.

That is, in step S043, the image matching is performed for the matching region based on the matching region set in step S011c.

On the other hand, when the setting information prescribes that the storing process is performed in a case where the machining mark shape F of the peripheral machining performed in advance in the periphery of the sample piece Q is recognized, the process of step S044 is executed.

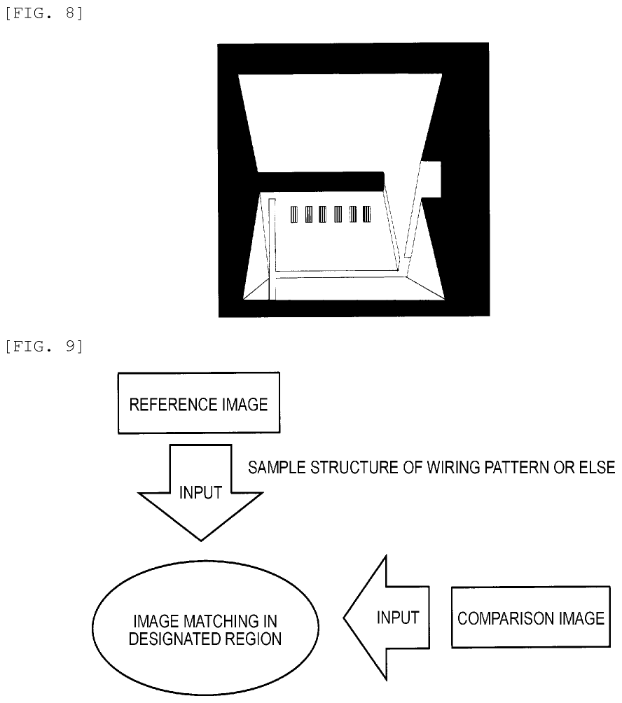

FIG. 9 is a conceptual diagram of the image matching when storing the region outside the frame line of the machining mark shape is selected. In step S044, as illustrated in FIG. 9, the computer 21 performs the image matching by using the reference image and the comparison image for the region (herein, for example, the region outside the frame line of the machining mark shape F) set in step S011c.

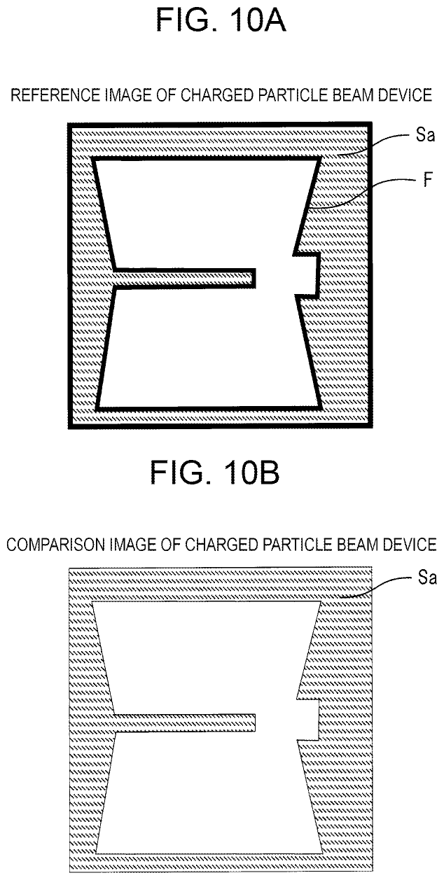

Herein, the example of the image matching when storing the designated region will be described. FIGS. 10A and 10B are conceptual diagrams illustrating the image matching when storing the designated region. The computer 21 performs the image matching is performed between the reference image and the comparison image illustrated in FIG. 10B for the region Sa between the machining mark shape F surrounded by the thick black solid line and the periphery of the reference image similarly indicated by a thick solid black line illustrated in FIG. 10A. That is, in step S044 as well, the image matching is performed on the matching region (herein, the region outside the frame line of the machining mark shape F) based on the matching region set in step S011c.

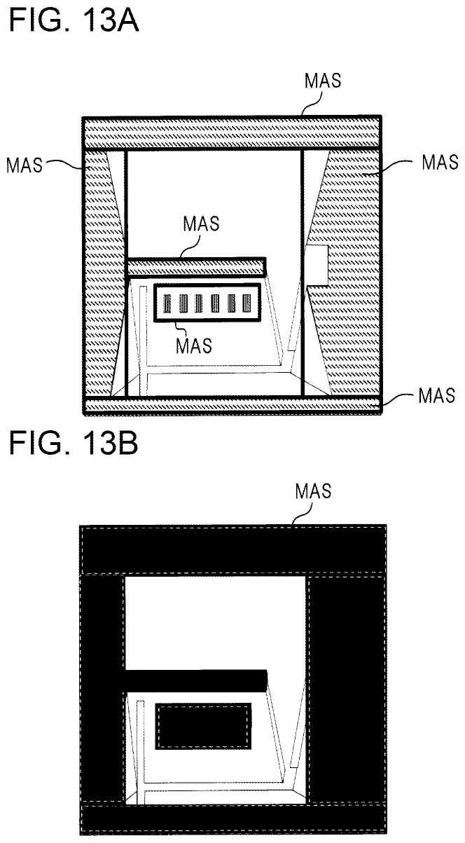

The image matching can also be performed in other manners. FIGS. 13A and 13B are diagrams illustrating another example of the image matching method. When the computer 21 stores arbitrary position, size, and number or designates the masking region MAS (FIG. 13A), the computer 21 selects whether to mask or store the image of the region inside the frame line of the designated masking region MAS.

When the masking process is selected, the computer 21 performs masking the masking region MAS in the reference image and the comparison image in step S043 (FIG. 13B) and performs the image matching for the masking region MAS.

On the other hand, when the storing process of storing the image of the region outside the frame line of the designated masking region MAS is selected, the computer 21 stores the designated region (here, the region inside the frame line of the sample piece shape Fa) and performs the image matching of the reference image and the comparison image in step S044, for example, as shown in FIG. 9.

Next, the computer 21 recognizes the position of the sample piece Q by the image matching in step S043 or S044 and position-aligns the sample piece Q (step S050).

Next, the computer 21 allows the needle driving mechanism 19 to move the needle (sample piece movement unit) 18 to an initial set position. Note that the needle driving mechanism 19 and the needle 18 may be combined as the sample piece movement unit. The initial set position is, for example, a predetermined position within a field-of-view region that is set in advance, such as a predetermined position in the periphery of the sample piece Q which has been position-aligned within the field-of-view region. After moving the needle 18 to the initial set position, the computer 21 allows the nozzle 17a at the tip of the gas supply unit 17 to approach a predetermined position in the periphery of the sample piece Q, for example, to lower the nozzle 17a from the standby position above the stage 12 in the vertical direction (step S060).

When moving the needle 18, the computer 21 can grasp the three-dimensional positional relationship between the needle 18 and the sample piece Q by using the reference mark Ref formed on the sample S during the execution of the automatic machining for forming the sample piece Q with high accuracy and can move the needle 18 appropriately.

Next, the computer 21 performs the following processes as the process of bringing the needle 18 into contact with the sample piece Q. First, the computer 21 switches to the absorption current image mode and recognizes the position of the needle 18 (step S070). The computer 21 detects the absorption current flowing into the needle 18 by irradiating the needle 18 with the charged particle beam while scanning and generates the absorption current image data by the charged particle beam irradiated from the plurality of different directions.

The absorption current image has an advantage that only the needle 18 can be reliably recognized without mistaking the needle 18 for the background. The computer 21 acquires the absorption current image data on an XY plane (plane perpendicular to the optical axis of the focused ion beam) by irradiation with the focused ion beam and acquires the absorption current image data on the XYZ plane (plane perpendicular to the optical axis of the electron beam) by irradiation with the electron beam. The computer 21 can detect the position of the tip of the needle 18 in the three-dimensional space by using each absorption current image data obtained from two different directions.

Herein, whether the shape of the needle 18 is good is determined (step S075). When it is determined that the needle 18 has a predetermined normal shape (OK), the process proceeds to the next step S080.

On the other hand, when it is determined in step S075 that the shape of the tip of the needle 18 is not attached with the sample piece Q due to deformation, damage, or the like (NG), a message such as “defective needle” is displayed to inform a warning to the operator of the apparatus (step S079), and the process proceeds to step S150. All the steps after step S080 are not executed, and the automatic sample sampling operation is ended. That is, when the shape of the tip of the needle is defective, no operation can be further performed, and the operator is required to replace the needle.

Herein, in the determination of shape of the needle in step S075, for example, when the position of the tip of the needle deviates from the predetermined position by 100 μm or more in the observation field of view of 200 μm on one side, the needle is determined to be defective.

Note that the computer 21 uses the detected position of the tip of the needle 18 to drive the stage 12 by the stage driving mechanism 13 so that the position of the tip of the needle 18 may be set to the center position (center of the field of view) of the preset field-of-view region.

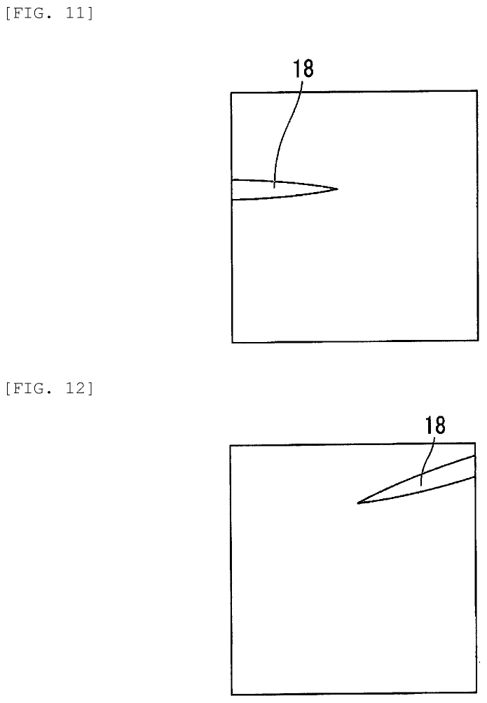

Next, the computer 21 acquires reference image data as the template for the template matching with respect to the shape of the tip of the needle 18 by using the detected position of the tip of the needle 18 (step S080). FIG. 11 is a diagram illustrating the template for the tip of the needle obtained by the focused ion beam. FIG. 12 is a diagram illustrating the template for the tip of the needle obtained by the electron beam. Herein, the fact that the orientation of the needle 18 differs between FIGS. 11 and 12 is because the same needle 18 is viewed from different observation directions due to differences in a positional relationship among the focused ion beam irradiation optical system 14, the electron beam irradiation optical system 15, and the detector 16 and a display orientation of the image by the secondary electrons.

The computer 21 drives the stage 12 by the stage driving mechanism 13 to irradiate the needle 18 with the charged particle beam (focused ion beam and electron beam) while scanning in a state where the sample piece Q is retracted outside the field of view. The computer 21 acquires each image data indicating the positional distribution in the plurality of different planes of the secondary charged particles (secondary electrons or secondary ions) R emitted from the needle 18 by irradiation with the charged particle beam. The computer 21 acquires the image data on the XY plane by irradiation with the focused ion beam and acquires the image data on the XYZ plane (plane perpendicular to the optical axis of the electron beam) by irradiation with the electron beam. The computer 21 acquires the image data by the focused ion beam and the electron beam and stores the image data as the templates (reference image data).

The computer 21 can performs the pattern matching with high accuracy regardless of the difference in shape of individual needles 18 since the image data actually acquired immediately before moving the needle 18 by coarse adjustment and fine adjustment to be described later is used as the reference image data. Since the computer 21 retracts the stage 12 and acquires each image data in a state where there is no complicated structure in the background, the computer 21 can acquire the template (reference image data) where the shape of the needle 18 can be grasped clearly by eliminating the influence of the background.

Note that, when acquiring each image data, the computer 21 uses image acquisition conditions such as suitable magnification, brightness, or contrast, which are stored in advance to increase the recognition accuracy of a target object. The computer 21 may use the absorption current image data as the reference image instead of using the image data by the secondary charged particles R as the reference image. Here, the computer 21 may acquire each absorption current image data for two different planes without driving the stage 12 to retract the sample piece Q from the field-of-view region.

When the process of step S080 ends, the initial setting process ends, and the sample piece pickup process is executed.

<Sample Piece Pickup Process>

Next, the sample piece pickup process will be described. In the sample piece pickup process, a process of picking up the sample piece Q from the sample S is performed in the automatic sample piece producing operation by the charged particle beam device 10a. Note that picking up in the present embodiment denotes separating and extracting the sample piece Q from the sample S by machining with the focused ion beam or by needle.

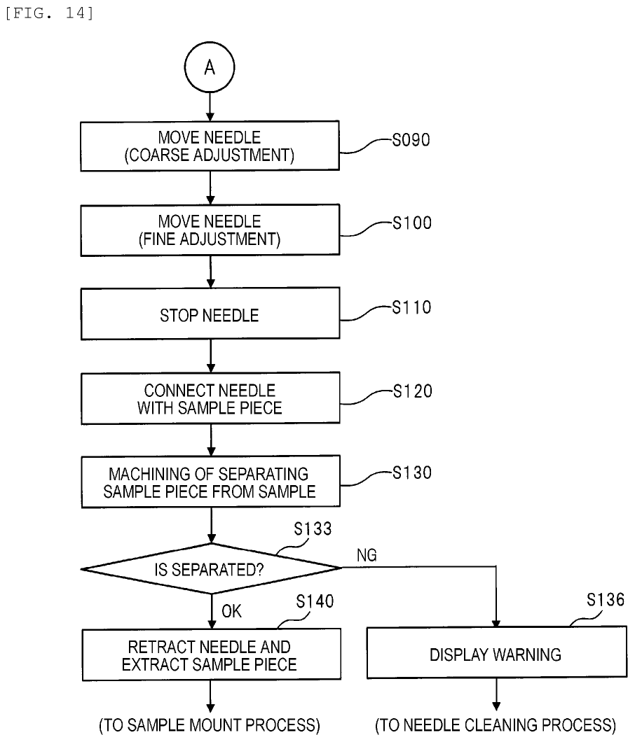

FIG. 14 is a flowchart illustrating an example of the sample piece pickup process according to the first embodiment of the present invention. As illustrated in FIG. 14, the sample piece pickup process includes steps S090 to S140.

First, in step S090, coarse adjustment movement of the needle 18 is performed. The computer 21 outputs the control signal to the needle driving mechanism 19 to move the needle 18 toward the sample piece Q. The computer 21 recognizes the reference mark Ref (FIG. 6) from each image data of the sample S obtained by the focused ion beam and the electron beam. The computer 21 sets a movement target position AP (FIG. 6) of the needle 18 by using the recognized reference mark Ref and the image data of the focused ion beam and the electron beam. The movement target position AP is a predetermined position on the sample piece Q or in the vicinity of the sample piece Q that is required to perform processing to connect the needle 18 and the sample piece Q to the deposition film. Specifically, the movement target position AP may be, for example, a position within the sample piece Q or a position slightly away from an edge of the sample piece Q. Thus, the movement target position AP is a position based on a predetermined positional relationship with respect to the machining range F when the sample piece Q is formed.

The computer 21 stores information on the relative positional relationship between the machining range F and the reference mark Ref when forming the sample piece Q on the sample S by irradiating the focused ion beam. Note that various types of information such as the information on the relative positional relationship between the machining range F and the reference mark Ref and the setting information may be stored in the ROM within the computer 21 or may be stored in other storage devices separated from the computer 21.

By using the recognized reference mark Ref, the computer 21 uses information on the reference mark Ref and the movement target position AP, or when necessary, the relative positional relationship between the machining range F and the reference mark Ref to move the tip of the needle 18 toward the movement target position AP in a three-dimensional space. When moving the needle 18 three-dimensionally, the computer 21 may, for example, move the needle 18 in the X and Y directions and then move the needle 18 in the Z direction.

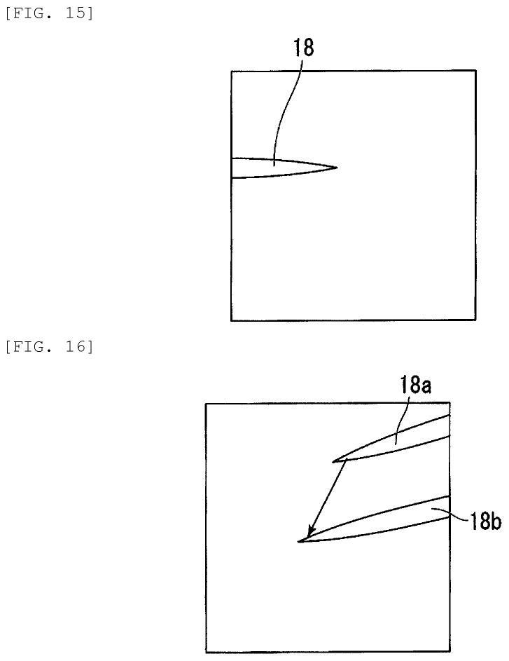

FIG. 15 is a diagram illustrating a vicinity of the tip of the needle in the image obtained by the focused ion beam of the charged particle beam device according to the first embodiment of the present invention. FIG. 16 is a diagram illustrating a vicinity of the tip of the needle in the image obtained by the electron beam of the charged particle beam device according to the first embodiment of the present invention. FIGS. 15 and 16 illustrate an aspect of the movement of the needle 18. Note that the reason why the direction of the needle 18 is different between FIGS. 15 and 16 is as explained with reference to FIGS. 11 and 12.

Although two needles 18a and 18b are illustrated in FIG. 16, FIG. 16 illustrates the image data of the vicinity of the tip of the needle 18 before and after the movement in the same field of view to illustrate the movement situation of the needle 18 in an overlapping manner. Therefore, the needles 18a and 18b are the same needle 18.

Next, in step S100, fine adjustment movement of the needle 18 is performed. The computer 21 repeatedly executes the pattern matching by using the reference image data to grasp the position of the tip of the needle 18 and outputs the control signal to the needle driving mechanism 19 to move the needle 18.

The computer 21 irradiates the needle 18 with the charged particle beam (the focused ion beam and the electron beam, respectively) and repeatedly acquires the image data from the charged particle beam. The computer 21 acquires the position of the tip of the needle 18 by performing pattern matching on the acquired image data by using the reference image data. The computer 21 moves the needle 18 within the three-dimensional space according to the acquired position of the tip of the needle 18 and the acquired movement target position AP.

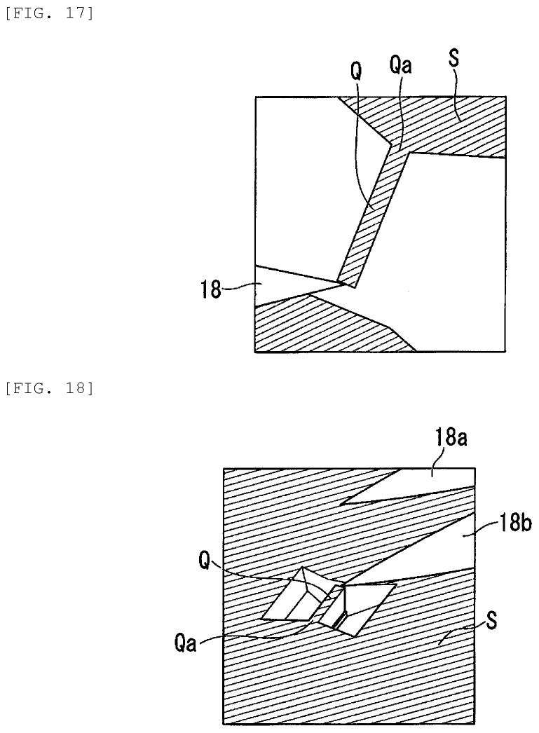

Next, the computer 21 performs a process of stopping the movement of the needle 18 (step S110). FIG. 17 is a diagram illustrating the tip of the needle and the sample piece in the image data obtained by the focused ion beam of the charged particle beam device according to the first embodiment of the present invention. FIG. 18 is a diagram illustrating the tip of the needle and the sample piece in the image data obtained by the electron beam of the charged particle beam device according to the first embodiment of the present invention. FIGS. 17 and 18 illustrate an aspect where the needle 18 is stopped. Note that, in FIGS. 17 and 18, similarly to FIGS. 11 and 12, the focused ion beam and the electron beam have different observation directions and different observation magnifications, but the observation target and the needle 18 are the same.

In step S110, the computer 21 moves the needle 18 in a state of irradiating the irradiation region including the movement target position AP with the charged particle beam. When the computer 21 determines that the absorption current flowing through the needle 18 exceeds a predetermined current or when the computer 21 determines that the coordinates of the tip of the needle have reached a predetermined movement target position AP, the computer 21 stops the driving of the needle 18 by the needle driving mechanism 19. Accordingly, the computer 21 arranges the position of the tip of the needle 18 at the movement target position AP.

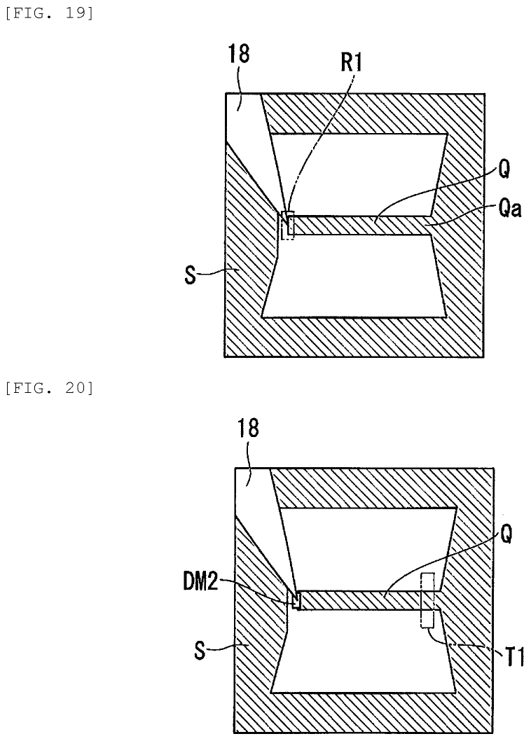

Next, the computer 21 performs a process of connecting the needle 18 to the sample piece Q (step S120). FIG. 19 is a diagram illustrating the machining range including connection machining positions of the needle and the sample piece in the image data obtained by the focused ion beam of the charged particle beam device according to the first embodiment of the present invention. FIG. 19 illustrates an aspect where the needle 18 is connected to the sample piece Q and illustrates a deposition film forming region DM2 (FIG. 20 described later) including the connection machining position between the needle 18 and the sample piece Q.

In step S120, the computer 21 designates the preset connection machining position by using the reference mark Ref of the sample S. The computer 21 sets the connection machining position to the position separated from the sample piece Q by a predetermined distance. The computer 21 sets an upper limit of the predetermined interval to, for example, 1 μm and preferably sets the predetermined interval to 100 nm or more and 200 nm or less. The computer 21 irradiates the irradiation region including a machining range R1 set at the connection machining position with the focused ion beam for a predetermined time and supplies gas to the sample piece Q and the tip surface of the needle 18 by the gas supply unit 17. Accordingly, the computer 21 connects the sample piece Q and the needle 18 by the deposition film DM2 (FIG. 20 described later).

In step S120, the computer 21 arranges the needle 18 at the slightly spaced position without directly contacting the sample piece Q, and connects the needle 18 and the sample piece Q by the deposition film. Accordingly, there is an advantage that problems such as damage to the sample piece Q and the sample S due to direct contact of the needle 18 with the sample piece Q can be prevented.

When connecting the needle 18 to the sample piece Q, the computer 21 selects the connection posture suitable for each approach mode (details will be described later) when transferring the sample piece Q connected to the needle 18 to the sample piece holder P later. The computer 21 sets the relative connection posture between the needle 18 and the sample piece Q corresponding to each of the plurality of different approach modes described later.

Note that the computer 21 may determine the state of connection by the deposition film by detecting a change in the absorption current of the needle 18. When the absorption current of the needle 18 reaches a predetermined current value, the computer 21 determines that the sample piece Q and the needle 18 are connected by the deposition film, and regardless of whether the predetermined time has elapsed, the computer 21 may stop forming the deposition film.

Next, the computer 21 performs processing of cutting the supporting portion Qa between the sample piece Q and the sample S (step S130). FIG. 20 is a diagram illustrating cut machining positions of the sample and the support portion of the sample piece in the image data obtained by the focused ion beam of the charged particle beam device according to the first embodiment of the present invention. FIG. 20 illustrates an aspect where the supporting portion Qa between the sample piece Q and the sample S is cut.

In step S130, the computer 21 designates a preset cut machining position T1 of a support portion Qa by using the reference mark Ref formed on the sample S. The computer 21 separates the sample piece Q from the sample S by irradiating the cut machining position T1 with the focused ion beam for a predetermined time.

Next, the computer 21 determines whether the sample piece Q is separated from the sample S by detecting electrical conduction between the sample S and the needle 18 (step S133). In step S133, after the cutting process is completed, that is, after the cutting of the support portion Qa between the sample piece Q and the sample S at the cut machining position T1 is completed, when conduction between the sample S and the needle 18 is detected, the computer 21 determines that the sample piece Q is not separated from the sample S (NG). When the computer 21 determines that the sample piece Q is not separated from the sample S (NG), the computer 21 notifies that the sample piece Q and the sample S is not completely separated from each other by displaying on the display device 20 or by a warning sound (step S136). Then, execution of the subsequent process is stopped, or needle cleaning is performed, and the next sampling is performed.

On the other hand, in step S133, when the computer 21 does not detect conduction between the sample S and the needle 18, the computer 21 determines that the sample piece Q has been separated from the sample S (OK), and proceeds to step S140.

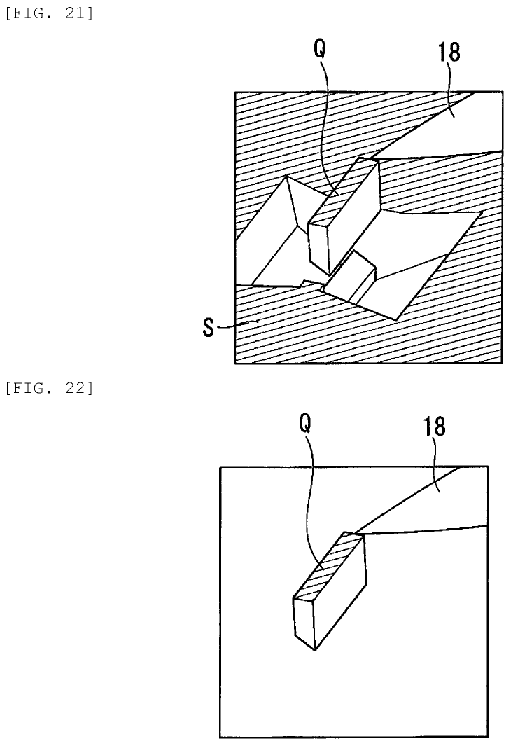

In step S140, the computer 21 performs the extraction of the needle 18 connected to the sample piece Q and the retraction of the needle 18. FIG. 21 is a diagram illustrating the state in which the sample piece is extracted in the image data obtained by the electron beam of the charged particle beam device according to the first embodiment of the present invention. FIG. 22 is a diagram illustrating the state in which the needle to which the sample piece is connected is retracted in the image data obtained by the electron beam of the charged particle beam device according to the first embodiment of the present invention.

The computer 21 allows the needle driving mechanism 19 to raise the needle 18 vertically upward (positive direction in the Z direction) by a predetermined distance. The degree (height) of raising the needle 18 differs between the extraction of the needle 18 and the retraction of the needle 18. Specifically, when extracting the needle 18, the needle 18 rises to a position where the sample piece Q connected to the needle 18 is higher than the sample S in the Z direction. On the other hand, when the needle 18 is retracted, the needle 18 connected to the sample piece Q rises to about the position in step S060.

<Other Configurations>

Heretofore, the basic procedure without pivoting of the needle 18 has been described, but the needle 18 can be pivoted by the needle driving mechanism 19. Therefore, a method of driving the needle 18 by using the pivoting of the needle 18 will be described below.

The computer 21 operates the needle driving mechanism 19 to rotate the needle 18 and the sample piece Q connected to the needle 18 so that, with respect to the sample piece Q extracted from the sample S, the surface of the sample S is perpendicular or parallel to the end surface of the columnar portion 34. Here, the computer 21 performs eccentricity correction to correct the rotation so that the sample piece Q does not deviate from the actual field of view.

Accordingly, the computer 21 can, for example, secure the posture of the sample piece Q suitable for finish machining to be performed later and reduce the influence of a curtain effect occurring during the thinning finish machining of the sample piece Q. The curtain effect refers to a phenomenon where a machining stripe pattern is formed by irradiation with the focused ion beam from a single direction due to a density difference and the like inside the sample, and thus, erroneous interpretation may be provided when the completed sample piece is observed with an electron microscope.

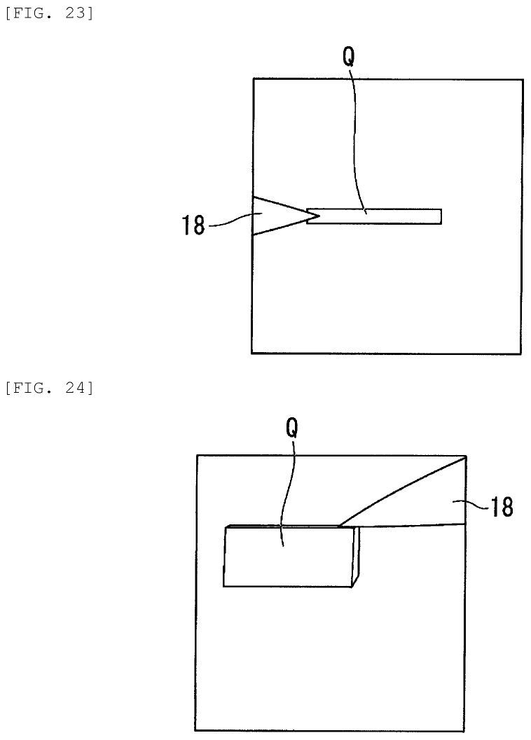

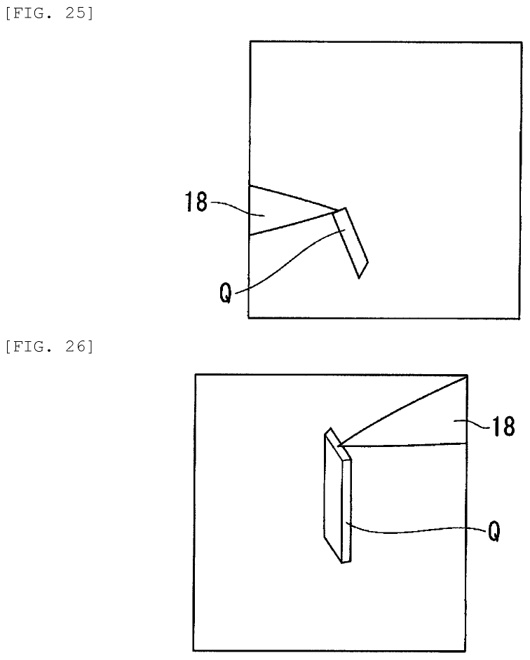

FIGS. 23 and 24 are diagrams illustrating the state of the vicinity of the tip of the needle when the needle is not rotated. FIGS. 25 to 28 are diagrams illustrating the state of the vicinity of the tip of the needle when the needle is rotated. Specifically, FIG. 23 illustrates the state of the needle 18 connected to the sample piece Q in the image data obtained by the focused ion beam in an approach mode of the needle at a rotation angle of 0°. FIG. 24 illustrates the state of the needle 18 connected to the sample piece Q in the image data obtained by the electron beam in the approach mode of the needle at a rotation angle of 0°.

In the approach mode of the needle 18 at a rotation angle of 0°, the computer 21 can set the posture state suitable for transferring the sample piece Q to the sample piece holder P without rotating the needle 18.

FIG. 25 illustrates the state in which the needle 18 connected to the sample piece Q in the image data obtained by the focused ion beam is rotated by 90° in the approach mode of the needle 18 at a rotation angle of 90°. FIG. 26 illustrates the state in which the needle 18 connected to the sample piece Q in the image data obtained by the electron beam is rotated by 90° in the approach mode of the needle 18 at a rotation angle of 90°.

In the approach mode of the needle 18 at a rotation angle of 90°, the computer 21 can set the posture suitable for transferring the sample piece Q to the sample piece holder P with the needle 18 rotated by 90°.

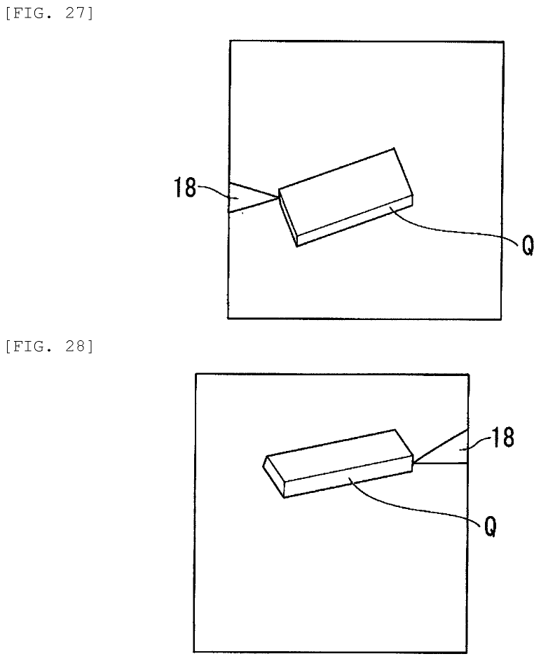

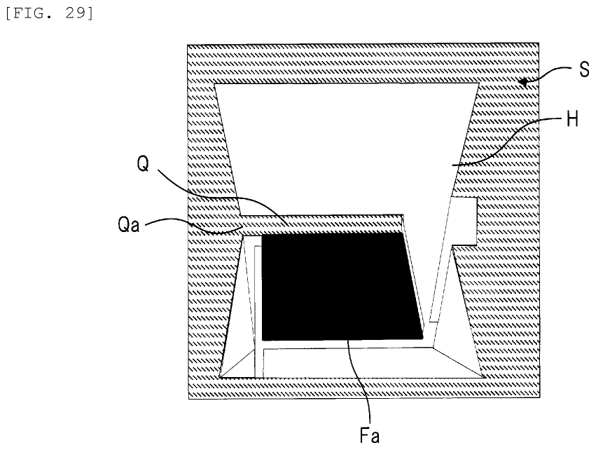

FIG. 27 illustrates the state in which the needle 18 connected to the sample piece Q in the image data obtained by the focused ion beam is rotated about 90° in the approach mode of the needle 18 at a rotation angle of 180°. FIG. 28 illustrates the state in which the needle 18 connected to the sample piece Q in the image data obtained by the electron beam is rotated about 90° in the approach mode of the needle 18 at a rotation angle of 180°. Note that, in the approach mode at a rotation angle 180°, the needle is rotated by 90°, and the mesh (not illustrated) is tilted by 90°, so that the sample is rotated by 180°.

In the approach mode of the needle 18 at a rotation angle of 180°, the computer 21 sets the posture state suitable for transferring the sample piece Q to the sample piece holder P with the needle 18 rotated by approximately 90°.

Note that the relative connection posture between the needle 18 and the sample piece Q is set to the connection posture suitable for each approach mode when the needle 18 is connected to the sample piece Q in the sample piece pickup process described above.

Due to the approach of the needle 18 to the sample piece Q at rotation angles of 0°, 90°, and 180°, the needle 18 approaches the movement target position AP from an appropriate direction by moving and rotating the stage 12 by the stage driving mechanism 13. Here, the positional relationship between the needle 18 and the sample piece Q when the needle 18 approaches the movement target position AP again can be changed by the rotation angle of the stage 12.

<Main Effects of the Present Embodiment>

According to the present embodiment, when the needle 18 approaches the sample piece Q, the computer 21 selects a matching region for performing image matching between a reference image obtained in advance by irradiating the sample with the charged particle beam and a comparison image obtained by irradiating the sample S, which is an extraction target for the sample piece Q, with the charged particle beam. According to such configuration, since the needle 18 can be reliably arranged in the vicinity of the sample piece Q, the automatic extraction of the sample piece Q can be performed accurately and stably.

According to the present embodiment, when the computer 12 recognizes the machining mark shape F of the peripheral machining performed in advance in the periphery of the sample piece Q, the computer 12 selects whether to perform the masking process of masking the image of the region outside the frame line of the machining mark shape F or to store the region outside the frame line of the machining mark shape. When the computer 21 selects the masking process, the computer 21 performs the image matching of the reference image and the comparison image in the region other than the region outside the frame line of the machining mark shape F on which the masking process has been performed. According to such configuration, since the needle 18 and the sample piece Q can be position-aligned more accurately, the automatic extraction of the sample piece Q can be performed accurately and stably.

According to the present embodiment, when the computer 12 recognizes the machining mark shape F of the peripheral machining performed in advance in the periphery of the sample piece Q, the computer 12 selects whether to perform the masking process of masking the image of the region outside the frame line of the machining mark shape F or to store the region outside the frame line of the machining mark shape. When the computer 21 selects storing, the computer 21 performs storing the image in the region outside the frame line of the stored machining mark shape F and performs the image matching of the reference image and the comparison image in the region outside the frame line of the machining mark shape F on which storing has been performed. According to such configuration, since the needle 18 and the sample piece Q can be position-aligned more accurately, the automatic extraction of the sample piece Q can be performed accurately and stably. The masking process can be omitted, and the load on the computer 21 is reduced.

According to the present embodiment, the computer 21 produces the template for the needle 18 based on the image obtained by irradiating the needle 18 with the charged particle beam before connecting to the sample piece Q. The computer 21 controls the charged particle beam irradiation optical system and the needle to irradiate the deposition film attached to the needle 18 with the charged particle beam based on the peripheral machining or the sample piece shape F obtained by the template matching using the template. According to such configuration, the posture of the sample piece Q connected to the needle 18 can be recognized, so that the sample piece Q can be conveyed to the sample piece holder P reliably.

According to the present embodiment, the display device 20 displaying the peripheral machining or the sample piece shape F is provided. According to such configuration, it is possible to notify the operator of an operating state of the charged particle beam device 10a, warning, or the like.

According to the present embodiment, the sample piece movement unit includes the needle 18 or tweezers connected to the sample piece Q. According to such configuration, the configuration of the sample piece movement unit can be freely changed according to the shape of the sample S and the sample piece Q, and versatility can be improved.

According to the present embodiment, the computer 21 specifies the position of the needle 18 or the machining location by the image matching. According to such configuration, since the needle 18 and the sample piece Q can be position-aligned more accurately, the automatic extraction of the sample piece Q can be performed accurately and stably.

### Second Embodiment

Next, a second embodiment will be described. In the present embodiment, in FIG. 7, when the sample piece shape Fa performed in advance in the periphery of the sample piece Q is recognized, the computer 21 may select whether to mask or store the image of the region inside the frame line of the sample piece shape Fa (step S011d in FIG. 5).

FIG. 29 is a diagram illustrating the reference image according to the second embodiment of the present invention. When the masking is selected in step S011d, as illustrated in FIG. 29, the computer 21 performs masking the image of the region inside the frame line of the sample piece shape Fa for the reference image and the comparison image (refer to step S011e in FIG. 5).

The computer 21 performs the image matching on the regions other than the regions for the reference image and the comparison image, where the masking is performed (step S043 in FIG. 2). That is, in the modified example, the image matching is performed on the region outside the frame line of the sample piece shape Fa based on the matching region set in step S011c in FIG. 5.

On the other hand, in step S011d, when the storing process of storing the region inside the frame line of the sample shape Fa is selected, in step S011f in FIG. 5, the process of storing the region inside the frame line of the sample shape Fa is executed. Then, the computer 21 performs the image matching by using the reference image and the comparison image for the designated region as illustrated in FIG. 9 (herein, the region inside the frame line of the sample piece shape Fa) (step S044 in FIG. 2).

<Main Effects of the Present Embodiment>

According to the present embodiment, when the computer 12 recognizes the sample piece shape Fa in the periphery of the sample piece Q, the computer 12 selects whether to perform the masking process of masking the image of the region inside the frame line of the sample piece shape Fa or to store the region inside the frame line of the sample piece shape. When the masking process is selected, the computer 12 performs the masking process on the reference image and the comparison image in the region inside the frame line of the sample piece shape Fa on which the masking process is performed. According to such configuration, since the needle 18 and the sample piece Q can be position-aligned more accurately, the automatic extraction of the sample piece Q can be performed accurately and stably.

According to the configuration where, when storing is selected, the computer 21 performs the masking process on the reference image and the comparison image in the region inside the frame line of the stored sample piece shape Fa, since the position-alignment between the needle 18 and the sample piece Q can be more accurately performed, the automatic extraction of the sample piece Q can be performed accurately and stably. The masking process can be omitted, and the load on the computer 21 is reduced.

### Third Embodiment

Next, a third embodiment will be described. In the present embodiment, the image matching using a training-completed model will be described.

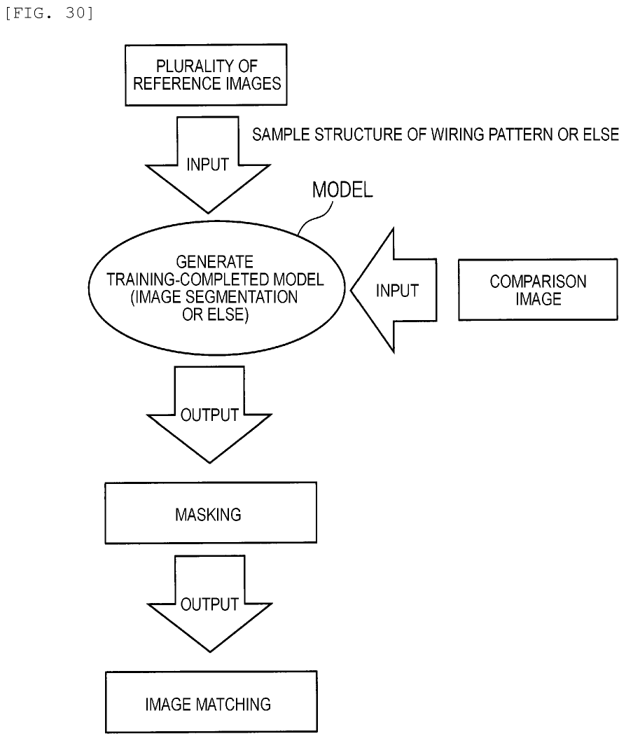

FIG. 30 is a conceptual diagram illustrating an example of the image matching using the training-completed model. As illustrated in FIG. 30, the computer 21 generates the training-completed model MODEL by training information on the plurality of sample structures of the sample from the plurality of images as reference images. The computer 21 performs the image recognition on the input comparison image by using the training-completed model MODEL. Then, the computer 21 performs masking the region of the comparison image that cannot be determined by image recognition. The computer 21 performs the image matching by using the reference image and the masked comparison image.

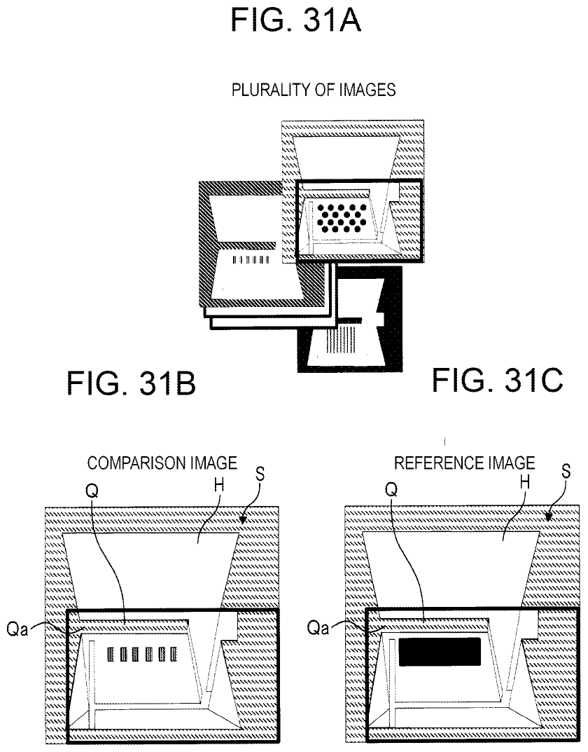

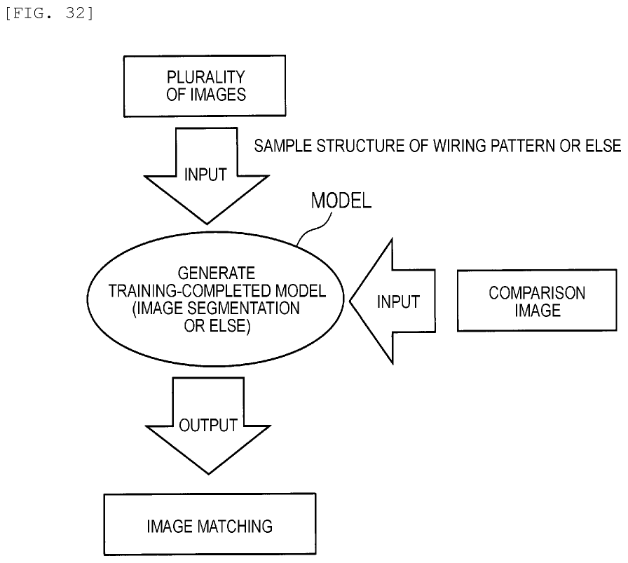

FIGS. 31A to 31C are diagrams illustrating another example of the image matching by using the training-completed model. The computer 21 designates the entire region of the reference image or the plurality of regions having arbitrary position and size of the reference image for the plurality of images acquired from the secondary electron images illustrated in FIG. 31A and stores and trains the images of the designated region as the reference images.

Then, the computer 21 acquires the comparison image illustrated in FIG. 31B from the secondary electron image obtained by irradiating the sample with the charged particle beam. The computer 21 compares the acquired comparison image with the stored reference image. When it is determined that the comparison image has a pattern similar to any region of the reference image, the computer 21 performs masking a region of the reference image where the pattern differs from that of the comparison image (FIG. 31C). Then, the computer 21 performs the matching process by using the masked reference image and the comparison image. Then, the computer 21 controls the needle driving mechanism 19 to approach the needle 18 to the sample S by using the matching result and the coordinates of the tip of the needle 18.

FIG. 32 is a conceptual diagram illustrating another example of the image matching by using the training-completed model. As illustrated in FIG. 32, the computer 21 generates the training-completed model MODEL in which information on the plurality of sample structures of the sample is trained in advance by using the plurality of images as reference images. The computer 21 performs an image recognition process on the input comparison image by using the training-completed model MODEL. Then, the computer 21 performs the image matching only on the regions of the comparison image that have been distinguished by the image recognition process.

The image recognition process is also executed when the training-completed model MODEL is produced. The image recognition process is executed by using, for example, well-known algorithms for performing image segmentation, image detection, and the like. The computer 21 extracts sample structure information from the image recognition results for the input image, machine-learns the configuration of the sample, and generates the training-completed model MODEL (reference image). The computer 21 performs the same image recognition process as when the training-completed model MODEL is produced for the comparison image. Note that different algorithms may be used when generating the training-completed model MODEL and when generating the comparison image.

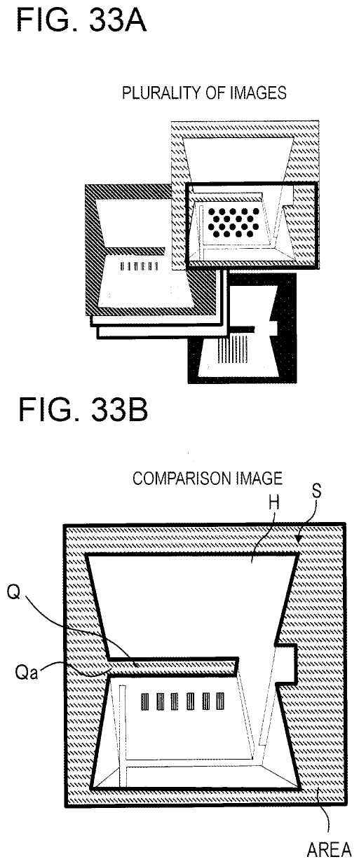

FIGS. 33A and 33B are diagrams illustrating a specific example of FIG. 32. The computer 21 designates the entire reference image or a plurality of arbitrary position/size regions of the reference image for a plurality of reference images acquired by the secondary election image, and stores and trains the images of the designated regions (FIG. 33A).

Then, the computer 21 acquires the comparison image from the secondary electron image obtained by irradiating the sample with the charged particle beam. The computer 21 compares the acquired comparison image with the stored image (image of the designated region). When the computer 21 determines that a pattern similar to any region of the image stored exists in the comparison image, the computer 21 performs the image matching process only in a region AREA of a similar pattern in the reference image and the comparison image (FIG. 33B). Then, the computer 21 controls the needle driving mechanism to approach the needle to the sample by using the matching result and the coordinates of the tip of the needle.

Note that the training-completed model may be produced by the computer 21 or may be produced by the external device.

<Main Effects of the Present Embodiment>

According to the present embodiment, the computer 21 generates the training-completed model MODEL by training information on the plurality of sample structures of the sample from the plurality of images as the reference images. Then, the computer 21 performs the image recognition process on the comparison image by using the trained-model MODEL and performs the masking process on the region that cannot be distinguished by the image recognition process on the comparison image. Then, the computer 21 performs the image matching by using the reference image and the masked comparison image. According to such configuration, even when the reference image and the comparison image do not completely match with each other, since the machining mark shape F and the sample piece shape Fa can be recognized by image recognition, the automatic extraction of the sample piece Q can be executed accurately and stably while improving versatility.

According to the present embodiment, the computer 21 performs the image recognition process on the comparison image by the image segmentation. With such configuration, algorithms for performing the image segmentation are readily available, and the image segmentation is easy to implement.

According to the present embodiment, when the computer determines that a pattern similar to any region of the reference image exists in the comparison image in the image recognition process for the comparison image by using the training-completed model, the computer performs masking the region of the reference image where the pattern is different from that of the comparison image. According to such configuration, since the image matching is performed only when the image recognition is successful, the automatic extraction of the sample piece Q can be performed accurately and stably.

In each embodiment described above, the computer 21 may implement each functional block by executing software, or a portion of the functional blocks may be configured by hardware such as LSI.

In each of the above-described embodiments, the needle 18 has been described as the example of the sharpened needle-shaped member, but the needle 18 may have a shape such as a flat chisel shape with a flat tip or may have a mechanism such as tweezers.

The computer 21 can collectively save data by linking set values such as acceleration (voltage or the like), current value, ion beam scan range, ion beam scan speed, ion beam scan time, and dose amount of the ion beam used for peripheral machining to file names. By calling up the saved data, machining can be performed under set conditions.

In each of the above-described embodiments, by setting the matching region in advance, the extraction of the sample including the acquisition of the reference image can be automatically performed. From a machining program used for peripheral machining, after recognizing the machining position and, at the same time, calculating the machining depth, and performing the peripheral machining, the SEM image is acquired with an FOV determined to be appropriate, and the same image is used as the reference image for sample template matching. The computer 21 automatically recognizes the peripheral machining mark and the sample piece shape in the reference image, performs masking the image outside the frame line of the peripheral machining mark and the image inside the frame line of the sample piece shape, and then performs matching the image with the comparison image by using the entire region of the reference image.

The embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

In the following description, preferred embodiments of the present invention are described.

(1) A charged particle beam device automatically extracting a sample piece from a sample, the device including: a sample stage on which the sample is mounted and moved; a charged particle beam irradiation optical system irradiating with a charged particle beam; a sample piece movement unit holding and conveying the sample piece extracted from the sample; a holder fixing table holding a sample piece holder to which the sample piece is transferred; and a computer, in which the computer generates a training-completed model obtained by training information on a plurality of sample structures of the sample from a plurality of images as a reference image, performs an image recognition process on a comparison image by using the training-completed model, and performs image matching on only a region in the comparison image that can be distinguished by the image recognition process.

(2) An automatic sample piece producing apparatus 10 according to the embodiment of the present invention is an automatic sample piece producing apparatus automatically producing a sample piece from a sample, the apparatus including at least: a plurality of charged particle beam irradiation optical systems (beam irradiation optical systems) irradiating with a charged particle beam; a sample stage on which the sample is mounted and moved; a sample piece transfer unit including a needle connected to the sample piece separated and extracted from the sample and conveying the sample piece; a holder fixing table holding a sample piece holder to which the sample piece is transferred; a gas supply unit supplying a gas for forming a deposition film by the charged particle beam; and a computer controlling at least the charged particle beam irradiation optical system and the sample piece transfer unit to form substantially the same shape as the needle before being connected to the sample piece by irradiating the needle separated from the sample piece with the charged particle beam based on an image of the needle by the charged particle beam acquired before being connected to the sample piece.

(3) An automatic sample piece producing apparatus 10 according to the embodiment of the present invention is an automatic sample piece producing apparatus automatically producing a sample piece from a sample, the apparatus including at least: a focused ion beam irradiation optical system (beam irradiation optical system) irradiating with a focused ion beam; a sample stage on which the sample is mounted and moved; a sample piece transfer unit including a needle connected to the sample piece separated and extracted from the sample and conveying the the sample piece; a holder fixing table holding a sample piece holder to which the sample piece is transferred; a gas supply unit supplying a gas for forming a deposition film by the focused ion beam; and a computer controlling at least the focused ion beam irradiation optical system and the sample piece transfer unit to form substantially the same shape as the needle before being connected to the sample piece by irradiating the needle separated from the sample piece with the focused ion beam based on an image of the needle by the focused ion beam acquired before being connected to the sample piece.

(4) In the automatic sample piece producing apparatus 10 described in (2) or (3) above, the charged particle beam includes at least a focused ion beam and an electron beam.

### REFERENCE SIGNS LIST

10: automatic sample piece producing apparatus
10a: charged particle beam device
11: sample chamber
12: stage (sample stage)
13: stage driving mechanism
14: focused ion beam irradiation optical system (charged particle beam irradiation optical system)
15: electron beam irradiation optical system (charged particle beam irradiation optical system)
16: detector
17: gas supply unit
18: needle
19: needle driving mechanism
20: display device
21: computer
22: input device
33: sample stage
34: columnar portion
P: sample piece holder
Q: sample piece
R: secondary charged particles
S: sample

1.-12. (canceled)

13. A charged particle beam device automatically extracting a sample piece from a sample, the device comprising:
a sample stage on which the sample is mounted and moved;
a charged particle beam irradiation optical system irradiating with a charged particle beam;
a sample piece movement unit holding and conveying the sample piece extracted from the sample;
a holder fixing table holding a sample piece holder to which the sample piece is transferred; and
a computer, wherein
when the sample has a repeating structure, the computer performs a process of masking a location of the sample having the repeating structure, and
when the sample piece movement unit approaches the sample piece, the computer selects a matching region for performing image matching between a reference image obtained in advance by irradiating the sample with the charged particle beam and a comparison image obtained by irradiating the sample, which is an extraction target for the sample piece, with the charged particle beam.

14. The charged particle beam device according to claim 13, wherein, when the computer recognizes a machining mark shape of peripheral machining performed in advance in the periphery of the sample piece, the computer selects whether to perform a masking process of masking an image of a region outside a frame line of the machining mark shape or to store the region outside the frame line of the machining mark shape and, when the masking process is selected, performs the image matching on the reference image and the comparison image in a region other than the region outside the frame line of the machining mark shape on which the masking process is performed.

15. The charged particle beam device according to claim 13, wherein, when the computer recognizes a machining mark shape of peripheral machining performed in advance in the periphery of the sample piece, the computer selects whether to perform a masking process of masking an image of a region outside a frame line of the machining mark shape or to store the region outside the frame line of the machining mark shape and, when storing is selected, performs the masking process image matching on the reference image and the comparison image in the stored region outside the frame line of the machining mark shape.

16. The charged particle beam device according to claim 13, wherein, when the computer recognizes a sample piece shape in the periphery of the sample piece, the computer selects whether to perform a masking process of masking an image of a region inside a frame line of the sample piece shape or to store the region inside the frame line of the sample piece shape and, when the masking process is selected, performs the image matching on the reference image and the comparison image in a region other than the region inside the frame line of the sample piece shape on which the masking process is performed.

17. The charged particle beam device according to claim 13, wherein, when the computer recognizes a sample piece shape in the periphery of the sample piece, the computer selects whether to perform a masking process of masking an image of a region inside a frame line of the sample piece shape or to store the region inside the frame line of the sample piece shape and, when storing is selected, performs the image matching on the reference image and the comparison image in the stored region inside the frame line of the sample piece shape.

18. A charged particle beam device automatically extracting a sample piece from a sample, the device comprising:
a sample stage on which the sample is mounted and moved;
a charged particle beam irradiation optical system irradiating with a charged particle beam;
a sample piece movement unit holding and conveying the sample piece extracted from the sample;
a holder fixing table holding a sample piece holder to which the sample piece is transferred; and
a computer, wherein
when the sample has a repeating structure, the computer performs a process of masking a location of the sample having the repeating structure, and
the computer generates a training-completed model obtained by training information on a plurality of sample structures of the sample from a plurality of images as a reference image, performs an image recognition process on a comparison image by using the training-completed model, performs a masking process on the comparison image in a region that cannot be distinguished by the image recognition process, and performs image matching by using the reference image and the comparison image on which the masking process is performed.

19. The charged particle beam device according to claim 18, wherein the computer performs the image recognition process on the comparison image by image segmentation.

20. A charged particle beam device automatically extracting a sample piece from a sample, the device comprising:
a sample stage on which the sample is mounted and moved;
a charged particle beam irradiation optical system irradiating with a charged particle beam;
a sample piece movement unit holding and conveying the sample piece extracted from the sample;
a holder fixing table holding a sample piece holder to which the sample piece is transferred; and
a computer, wherein
when the sample has a repeating structure, the computer performs a process of masking a location of the sample having the repeating structure, and
the computer generates a training-completed model obtained by training information on a plurality of sample structures of the sample from a plurality of images as a reference image, performs an image recognition process on a comparison image by using the training-completed model, and when determining that a pattern similar to any region of the reference image exists in the comparison image, performs masking the reference image in a region of which pattern is different from that of the comparison image.

21. The charged particle beam device according to claim 13, wherein the computer produces a template for the sample piece movement unit based on the image acquired by irradiating the sample piece movement unit with the charged particle beam before connecting to the sample piece and controls the charged particle beam irradiation optical system and the sample piece movement unit to irradiate a deposition film attached to the sample piece movement unit with the charged particle beam based on peripheral machining or the sample piece shape obtained by template matching using the template.

22. The charged particle beam device according to claim 21, further comprising a display device displaying the peripheral machining or the sample piece shape.

23. The charged particle beam device according to claim 13, wherein the sample piece movement unit includes a needle or tweezers connected to the sample piece.

24. The charged particle beam device according to claim 13, wherein the computer specifies a position or a machining location of the sample piece movement unit by the image matching.
